(19) United States
(12) Patent Application Publication
(10) Pub. No.: US 2006/0145791 A1
(43) Pub. Date: Jul. 6, 2006

(54) Variable reactance tuning circuit

(76) Inventor: George Hedley Storm Rokos, Little Samford, Essex (GB)

Correspondence Address: Bryan W. Bockhop;ARNALL GOLDEN GREGORY, 2800 One Atlantic Center, 1201 West Peachtree Street, Atlanta, GA, 30309-3450, US

(21) Appl. No.: 10/485,583

(22) PCT Filed: Aug. 2, 2002
(86) PCT No.: PCT/GB02/03540

§ 371 Date: Mar. 6, 2006

(30) Foreign Application Priority Data
Aug. 2, 2001 (GB) 0118826.7

(51) Int. Cl. H03H 5/12

(52) U.S. Cl. 334/15

(57) ABSTRACT

A variable reactance tuning circuit includes a variable capacitance diode (2) having a first terminal coupled to a ground reference potential line (5) and a second terminal coupled, via a bias resistor (4) to a control voltage supply line (3). Nodes (6 and 7), coupled to the first and second terminals of the variable capacitance diode (2), provide active and ground reference inputs to a tunable circuit such as an oscillator circuit or a filter circuit (not shown). A diode (8) is coupled in parallel with the bias resistor (4) so that the anode of the diode (8) is coupled to the control voltage supply line (3) and the cathode is coupled to the active node (6). By providing rectification of the control voltage at the active node (6) at all times, the average voltage at the active node (6) can be allowed to exceed the control voltage so that there can be more voltage pumping at higher voltages for a given circulating current.

### FIELD OF THE INVENTION

This invention relates to a variable reactance tuning circuit, particularly, though not exclusively, to such a circuit which provides a controllable reactance for modifying a resonance frequency or frequencies of a tunable circuit.

### BACKGROUND OF THE INVENTION

A variable reactance tuning circuit is conventionally used to provide a resonance-modifying reactive impedance to a tunable circuit, such as an oscillating circuit or a filter circuit. A variable reactance tuning circuit can have problems with rectification when the tuned signal is large and the control signal is in a specific part of the desired control range. A well known example of such a situation is the control of a variable capacitance diode, also known as a varactor, operating at a small reverse bias. Such tuning circuits generally include a variable capacitor diode (varactor) and a bias resistor, each having a first end coupled to each other, and a second end coupled, directly or indirectly to a respective one of a pair of relative potential supply lines. An output node between the varactor and the bias resistor is coupled to a drive input terminal of the tunable circuit. Thus, the varactor could be coupled between the output node and a ground reference potential supply, while the bias resistor is coupled to a control voltage supply, or vice versa, with or without other components coupled between the varactor, and/or the bias resistor, and the respective relative potential supply line.

When a varactor is used to tune a tunable circuit that has a significant signal amplitude at the tuned frequency, the minimum average voltage across the varactor can become limited due to the varactor rectifying the voltage. This can severely restrict the available tuning range, which is dependent on the voltage available at the output node of the variable capacitance tuning circuit. This is particularly so if the control voltage, at the tunable circuit side, is limited, for example, due to low power circuits powered by batteries.

### BRIEF SUMMARY OF THE INVENTION

The present invention therefore seeks to provide a variable reactance tuning circuit, which overcomes, or at least reduces the above-mentioned problems of the prior art.

Accordingly, in a first aspect, the invention provides a variable reactance tuning circuit comprising a variable reactance having a first terminal coupled to a first relative potential supply line and a second terminal coupled to a second relative potential supply line by means including at least a first diode, the first diode having a first terminal coupled to the second terminal of the variable reactance and a second terminal coupled to the second relative potential supply line, means, coupled to the first diode, for supplying current through the first diode when the first diode is reverse biased, in use the current flowing in a direction that will tend to reduce the reverse bias, tuning output nodes suitable for responding to cyclical current in a tunable circuit, one of said nodes being coupled to the second terminal of the variable reactance.

In a preferred embodiment, the variable reactance is a variable capacitance diode and the coupled terminals of the variable capacitance diode and the first diode are of the same polarity. Preferably, the means for supplying current through the first diode is a bias resistor

In a preferred embodiment, the circuit further comprises a second diode having a first terminal coupled to the first terminal of the variable reactance and a second terminal coupled to the first relative potential supply line, wherein the coupling polarity of the second diode relative to the first relative potential supply line is inverted as compared to the coupling polarity of the first diode and the second relative potential supply line and further comprising means, coupled to the second diode, for supplying current through the second diode when the second diode is reverse biased, such that in use the current flows in a direction that will tend to reduce the reverse bias.

Preferably, the means for supplying current through the second diode is a second bias resistor. Preferably, the first terminal of the diode is a cathode and the second terminal of the diode is an anode.

In a further embodiment, the circuit preferably further comprises a further bias resistor coupled between the variable reactance and the first relative potential supply line, and having a first terminal coupled to the first terminal of the variable reactance and a second terminal coupled to the first relative potential supply line.

The circuit preferably further comprises a capacitor having a first terminal coupled to the first terminals of the further bias resistor and the variable reactance and a second terminal coupled to the second relative potential supply line. Preferably, the or each diode coupled between the variable reactance and a relative potential supply line is connected in series with a respective switch, such that the effect of the respective diode can be rendered negligible. In a preferred embodiment, the or each switch comprises a switching transistor having current electrodes coupled between the cathode of the respective diode and the respective relative potential supply line and a gate electrode coupled to a selection terminal for receiving a selection signal. The switching transistor is preferably a MOSFET (Metal on Silicon Field Effect Transistor).

The tunable circuit can be an oscillator circuit comprising an oscillator having an input terminal coupled to the tuning output node of the variable capacitance tuning circuit, or a filter circuit comprising a filter section having tuning terminals coupled to the tuning output nodes of the variable reactance tuning circuit.

### BRIEF DESCRIPTION OF THE DRAWINGS

Several embodiments of the invention will now be more fully described, by way of example, with reference to the drawings, of which:

FIG. 1 shows a schematic circuit diagram of a simple conventional varactor bias circuit;

FIG. 2 shows a schematic circuit diagram of a simple varactor bias circuit according to a first embodiment of the present invention;

FIG. 3 shows a schematic circuit diagram of a conventional varactor bias circuit with both ends of the varactor available for coupling to a tunable circuit;

FIG. 4 shows a schematic circuit diagram of a varactor bias circuit with both ends of the varactor available for coupling to a filter circuit according to a second embodiment of the present invention;

FIG. 5 shows a schematic circuit diagram of a conventional varactor bias integrated circuit; and

FIG. 6 shows a schematic circuit diagram of a varactor bias integrated circuit according to a third embodiment of the present invention.

### DETAILED DESCRIPTION OF THE DRAWINGS

Thus, as shown in FIG. 1, a conventional varactor bias circuit 1 is composed of a variable capacitance diode 2 having a first terminal coupled to a ground reference potential line 5 and a second terminal coupled, via a bias resistor 4 to a control voltage supply line 3. Nodes 6 and 7, coupled to the first and second terminals of the variable capacitance diode 2, provide active and ground reference inputs to a tunable circuit, such as an oscillator circuit or a filter circuit (not shown).

It will be appreciated that the voltage on the active node 6 will be oscillating, and will therefore have maximum and minimum peak voltages which can be substantially larger and smaller than the nominal voltage at that point. In low voltage applications, as the control voltage is reduced to very small voltages, e.g. below 1 Volt, then the signal swing on the variable capacitance diode 2 will, at times, cause the variable capacitance diode to conduct, so that the average voltage on the active node 6 is no longer the same as that on the control voltage supply line 3 (due to rectification by the variable capacitance diode), but can be positive relative to the control voltage supply line 3.

Turning now to FIG. 2, a first embodiment of the present invention is illustrated, where the same elements as in FIG. 1 have the same reference numbers. In this case, a diode 8 is coupled in parallel with the bias resistor 4 so that the anode of the diode 8 is coupled to the control voltage supply line 3 and the cathode is coupled to the active node 6. By providing rectification of the control voltage at the active node 6 at all times, the average voltage at the active node 6 can be allowed to exceed the control voltage so that there can be more voltage pumping at higher voltages for the same circulating current, than in the circuit of FIG. 1. Indeed, it is possible for the range of the short-term average voltage across the variable capacitance diode 2 to exceed the control voltage on line 3. This effect results from the increase in the RF impedance of the variable capacitance diode 2 with increasing potential applied across it.

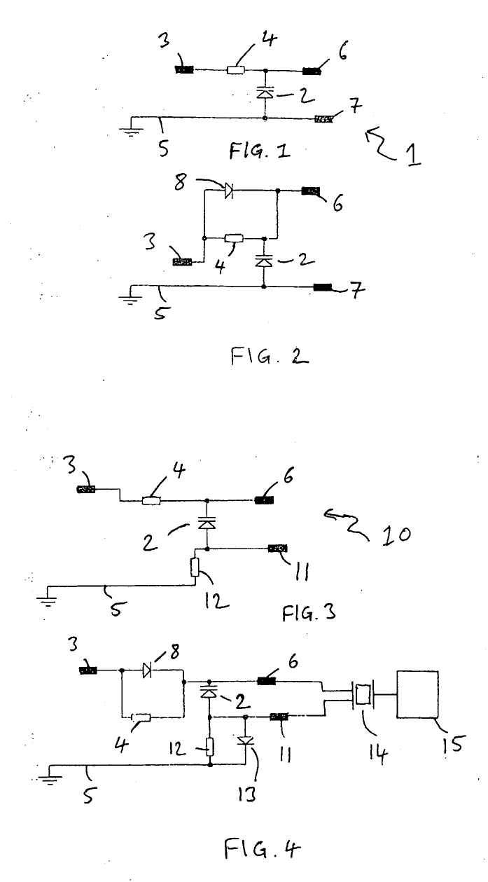

FIG. 3 shows a known varactor bias circuit 10, which is substantially identical to that of FIG. 1 and with the same elements having the same reference numbers. In this case, however, both ends of the variable capacitance diode 2 are maintained at a “live” potential for coupling to the tunable circuit at the active node 6 and a live node 11, which is maintained above the ground reference potential on line 5 by a second bias resistor 12.

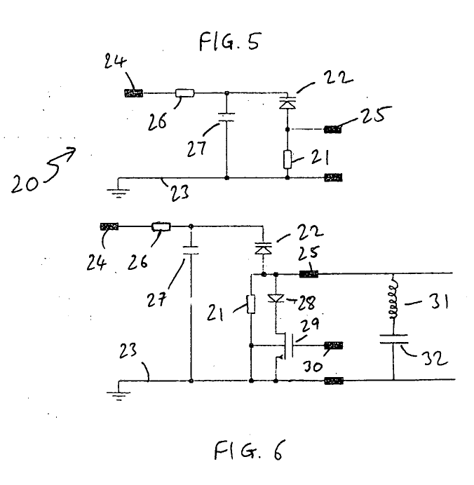

In a second embodiment of the present invention, as shown in FIG. 4, in which the same components have the same reference numbers as in FIG. 3, the first bias resistor 4 has a first diode 8 coupled in parallel with it, as described above with reference to FIG. 2. A second diode 13 is also coupled in parallel with the second bias resistor 12. By having both ends of the variable capacitance diode 2 controlled by the self-pumping diodes 8 and 13, the variable capacitance diode 2, the rectification-free region is extended. This is especially important for hyper-abrupt variable capacitance diodes. There are also situations where the oscillation voltage is “in phase” on the two terminals of the variable capacitance diode. This is a situation where the use of the two self-pumping diodes can maintain the variable capacitance diode potential well above zero at all times, and thus match the operating range to the most sensitive pulling region of some types of variable capacitance diodes. An oscillator 14 controlled by an oscillator control circuit 15 is shown coupled to the active and live nodes 5 and 11.

Of course, the amplitude of oscillation can vary due to noise, power supply variations, and by feedback of the output signal. Such variations can change the pumping level and therefore the output frequency of the tunable circuit. This is especially true where the varactor bias circuit is manufactured in an integrated form, as shown in FIG. 5. In this case, the integrated varactor bias circuit 20 has the bias resistor 21 and the variable capacitance diode 22 coupled to each other between the ground reference potential supply line 23 and the control voltage supply line 24 in the opposite manner to that of FIG. 1, that is, with the variable capacitance diode 22 coupled between the active node 25 and the control voltage supply line 24 and the bias resistor 21 coupled between the active node 25 and the ground reference potential supply line 23. Of course, the cathode of the variable capacitance diode 22 is still maintained at a higher potential than the anode, as before, in order to maintain the reverse bias. In this case, a second bias resistor 26 is coupled between the variable capacitance diode 22 and the control voltage supply line 24, with a capacitor 27 being coupled between the junction between the second bias resistor 26 and the variable capacitance diode 22 and the ground reference potential supply line 23.

In a third embodiment of the present invention, as shown in FIG. 6, in which the same components have the same reference numbers as in FIG. 5, the bias resistor 21 has a self-pumping diode 28 coupled in parallel therewith between the active node 25 and the ground reference potential supply line 23. In this case, however, especially for very small packages, where it is not always practical to reduce the coupling between the output and the tunable circuit sufficiently that output drive level variations will not cause significant amplitude variations, a switching transistor 29 is coupled between the self-pumping diode 28 and the ground reference potential supply line 23 so that the self-pumping diode 28 can be switched out of the circuit, when required. The switching transistor 29 is a MOSFET transistor having its drain coupled to the self-pumping diode 28 and its source coupled to the ground reference potential supply line 23. A control signal line 30 is coupled to the gate of the MOSFET transistor 29 to control its switching, and the substrate of the MOSFET transistor 29 is coupled to the ground reference potential supply line 23. A filter section, having an inductor 31 and a capacitor 32, is shown coupled to the active node 25.

This arrangement with the variable capacitance diode (varactor) 22 in series with fixed capacitor 27 has specific advantages for use with integrated circuit varactors. This is because the peak-to-peak potential at node 25 is greater than the potential across the varactor. This, in turn, allows self pumping diode 28 to be a small area diode, constructed using the same diffusions as the varactor diode, without reducing the range of relative potential supply line 24, which operates without significant forward conduction of the varactor.

It will thus be clear that, by utilizing the same signal swing that causes the rectification problem in the variable reactance to drive a rectifying component of relatively high impedance in the bias circuit, causes the potential across the variable reactance to increase, relative to the unmodified control potentials, throughout the adjustment range. The consequent increase in maximum mean potential across the variable reactance can recover much, and sometimes all, of the reactance range that was previously lost to rectification.

It will be appreciated that although only three particular embodiments of the invention has been described in detail, various modifications and improvements can be made by a person skilled in the art without departing from the scope of the present invention. For example, as will be appreciated, the oscillator circuit of FIG. 4 can replace the filter section of FIG. 6, and vice versa. Furthermore, although the switching transistor 29 of FIG. 6 has been described as a MOSFET, it will be appreciated that it could be another type of transistor, or even not a transistor at all, but some other type of switching device, such as a micro-mechanical switch or silicon switch.

1. A variable reactance tuning circuit comprising:
a variable reactance having a first terminal coupled to a first relative potential supply line and a second terminal coupled to a second relative potential supply line by means including at least a first diode, the first diode having a first terminal coupled to the second terminal of the variable reactance and a second terminal coupled to the second relative potential supply line;
means, coupled to the first diode, for supplying current through the first diode when the first diode is reverse biased, in use the current flowing in a direction that will tend to reduce the reverse bias;
tuning output nodes suitable for responding to cyclical current in a tunable circuit, one of said nodes being coupled to the second terminal of the variable reactance.

2. A variable reactance tuning circuit according to claim 1, wherein the means for supplying current through the first diode is a bias resistor.

3-14. (canceled)

15. A variable reactance tuning circuit according to claim 1, wherein the variable reactance is a variable capacitance diode and wherein the coupled terminals of the variable capacitance diode and the first diode are of the same polarity.

16. A variable reactance tuning circuit according to claim 1, further comprising a second diode having a first terminal coupled to the first terminal of the variable reactance and a second terminal coupled to the first relative potential supply line, wherein the coupling polarity of the second diode relative to the first relative potential supply line is inverted as compared to the coupling polarity of the first diode and the second relative potential supply line and further comprising means, coupled to the second diode, for supplying current through the second diode when the second diode is reverse biased, such that in use the currant flows in a direction that will tend to reduce the reverse bias.

17. A variable reactance tuning circuit according to claim 16, wherein the means for supplying current through the second diode is a second bias resistor.

18. A variable reactance tuning circuit according to claim 1, further comprising a further bias resistor coupled between the variable reactance and the first relative potential supply line, and having a first terminal coupled to the first terminal of the variable reactance and a second terminal coupled to the first relative potential supply line.

19. A variable reactance tuning circuit according to claim 18, further comprising a capacitor having a first terminal coupled to the fist terminals of the further bias resistor and the variable reactance and a second terminal coupled to the second relative potential supply line.

20. A variable reactance tuning circuit according to claim 1, wherein the or each diode coupled between the variable reactance and a relative potential supply line is connected in series with a respective switch, such that the effect of the respective diode can be rendered negligible.

21. A variable reactance tuning circuit according to claim 20, wherein the or each switch comprises a switching transistor having current electrodes coupled between the cathode of the respective diode and the respective relative potential supply line and a gate electrode coupled to a selection terminal for receiving a selection signal.

22. A variable reactance tuning circuit according to claim 21, wherein the or each switching transistor is a MOSFET (Metal on Silicon Field Effect Transistor).

23. An oscillator circuit comprising an oscillator having an input terminal coupled to the tuning output node of a variable reactance tuning circuit according to claim 1.

24. A filter circuit comprising a filter section having tuning terminals coupled to the tuning output nodes of a variable reactance tuning circuit according to claim 1.
